(19) United States
(12) Patent Application Publication
(10) Pub. No.: US 2025/0285991 A1
(43) Pub. Date: Sep. 11, 2025

(54) SYSTEM IN PACKAGE MODULE AND METHOD FOR FABRICATING THE SAME

(71) Applicant: USI Science and Technology (Shenzhen) Co., Ltd., Guangdong Province (CN)

(72) Inventor: LI-CHENG SHEN, Guangdong Province (CN)

(21) Appl. No.: 19/023,187

(22) Filed: Jan. 15, 2025

(30) Foreign Application Priority Data
Mar. 7, 2024 (CN) 202410265920.X

(51) Int. Cl. H01L 23/552; H01L 21/56; H01L 23/06; H01L 23/31; H01L 25/07

(52) U.S. Cl. CPC H01L 23/552; H01L 21/561; H01L 23/06; H01L 23/3107; H01L 25/072

(57) ABSTRACT

A system in package module and the method for fabricating the same are provided. The method includes providing a circuit substrate and disposing electronic components and metal grids on this circuit substrate. The height of each metal grid is larger than each electronic component. Each metal grid includes several openings, while the side wall of each opening surrounds at least one electronic component. An encapsulation layer is formed on the circuit substrate after the electronic components and metal grids are disposed. The encapsulation layer covers a part of metal grids but exposes the surfaces of these metal grids. An electromagnetic shielding layer is formed on the encapsulation layer and is electrically connected to the metal grids through their surfaces. After the electromagnetic shielding is formed, the electromagnetic shielding layer, the encapsulation layer and the circuit substrate is cut along the spacing between the metal grids.

### RELATED APPLICATIONS

This application claims priority to China Application Serial Number 202410265920.X, filed Mar. 7, 2024, which is herein incorporated by reference in its entirety.

### BACKGROUND

### Technical Field

The present disclosure relates to an electronic package module. More particular, the present disclosure relates to an electronic package module included in system in package (SiP) modules and the method for fabrication of the same.

### Description of Related Art

In the trend of developing thinner and lighter electronic products, the spacing between electronic components disposed on circuit board is gradually reduced. In order to avoiding the interference between the electronic components, the electromagnetic shielding materials (e.g. metals) are disposed between those electronic components which interfere with each other. As for the electromagnetic shielding of system in package modules, the modules are categorized into “compartment electromagnetic shielding” which prevents electronic components within a single module from interfering with each other, and “conformal electromagnetic shielding” which prevents electronic components of different modules from interfering with each other.

In general, after the electronic components are surrounded by molding compound, the region where the electromagnetic shielding material is to be formed is ablated by laser, and the trenches formed by laser ablation are filled with electromagnetic shielding materials, so that the compartment electromagnetic shielding effect is achieved. The cutting process is conducted to form several singular package modules after the compartment electromagnetic shielding structure is formed. Afterward, the electromagnetic shielding layers are formed on singular package modules by sputtering, and thus the conformal electromagnetic shielding effect is achieved.

However, the copper layers of the circuit substrate have to be exposed on the side surface of the package modules after cutting process, so that the electromagnetic shielding layer can be electrically connected to the circuit substrate for grounding. These copper layers are prone to be oxidized or contaminated during the processes, so that the electromagnetic shielding may be influenced. In addition, the aforementioned method of forming electromagnetic shielding has limited economic benefit due to the high costs of equipment and time for laser ablation.

### SUMMARY

Accordingly, the disclosure is to provide a system in package module and the method for fabrication of the same, thereby enhancing the electromagnetic shielding effect of the system in package module.

At least one embodiment of the disclosure provides a method for fabricating a system in package module including providing a circuit substrate. A plurality of electronic components are disposed on the circuit substrate. A plurality of metal grids are disposed on the circuit substrate, and each of the plurality of metal grids includes a plurality of openings. A side wall of each of the plurality of openings encircles at least one of the plurality of electronic components separately, and a height of each of the plurality of metal grids is larger than a height of each of the plurality of electronic components. An encapsulation layer is formed on the circuit substrate after the plurality of electronic components and the plurality of metal grids are disposed. The encapsulation layer covers the plurality of electronic components and a part of the plurality of metal grids and exposes a surface of the plurality of metal grids. An electromagnetic shielding layer is formed on the encapsulation layer. This electromagnetic shielding layer covers the plurality of electronic components and is electrically connected to the plurality of metal grids through the surface of the plurality of metal grids. The electromagnetic shielding layer, the encapsulation layer and the circuit substrate are cut along a plurality of spacing located between each of the plurality of metal grids after the electromagnetic shielding layer is formed.

At least one embodiment of the disclosure provides a system in package module. The system in package module includes a circuit substrate, at least two electronic components, a metal grid, an encapsulation layer and an electromagnetic shielding layer. The electronic components and the metal grid are disposed on the circuit substrate, and the metal grid includes a plurality of openings. A side wall of each of the plurality of openings encircles at least one of the electronic components separately, and a height of the metal grid is larger than a height of the electronic components. The encapsulation layer surrounds the electronic components and a part of the metal grid and exposes a surface of the metal grid. The electromagnetic shielding layer covers the electronic components, the metal grid and the encapsulation layer, while the electromagnetic shielding layer is electrically connected to the metal grid through the surface.

According to the aforementioned embodiments, the metal grids are disposed on the circuit substrate where the electronic components are disposed, so that the electromagnetic shielding in lateral direction is built up. After the encapsulation layer and the electromagnetic shielding layer on the encapsulation are formed, the spacing between the metal grids is cut, and thus the plurality of system in package modules are formed. Therefore, the connection structures of the circuit substrate (e.g. pads) which are connected to the metal grids will still be surrounded by the encapsulation layer after the cutting process, so that the connection structures are prevented from oxidation or contamination due to the exposure to environment, thereby increasing reliability of the electromagnetic shielding effect.

### BRIEF DESCRIPTION OF THE DRAWINGS

To illustrate more clearly the aforementioned and the other features, merits, and embodiments of the present disclosure, the description of the accompanying figures are as follows:

FIG. 1A to FIG. 1E illustrate cross-sectional views of a method for fabricating a system in package module in accordance with one embodiment of the present disclosure.

FIG. 2 illustrates a top view of the method for fabricating a system in package module in accordance with the embodiment of FIG. 1B.

FIG. 3 illustrates a cross-sectional view of a method for fabricating a system in package module in accordance with one embodiment of the present disclosure.

FIG. 4 illustrates a top view of a shielding mask in accordance with one embodiment of the present disclosure.

FIG. 5 illustrates a cross-sectional view of a system in package module in accordance with one embodiment of the present disclosure.

### DETAILED DESCRIPTION

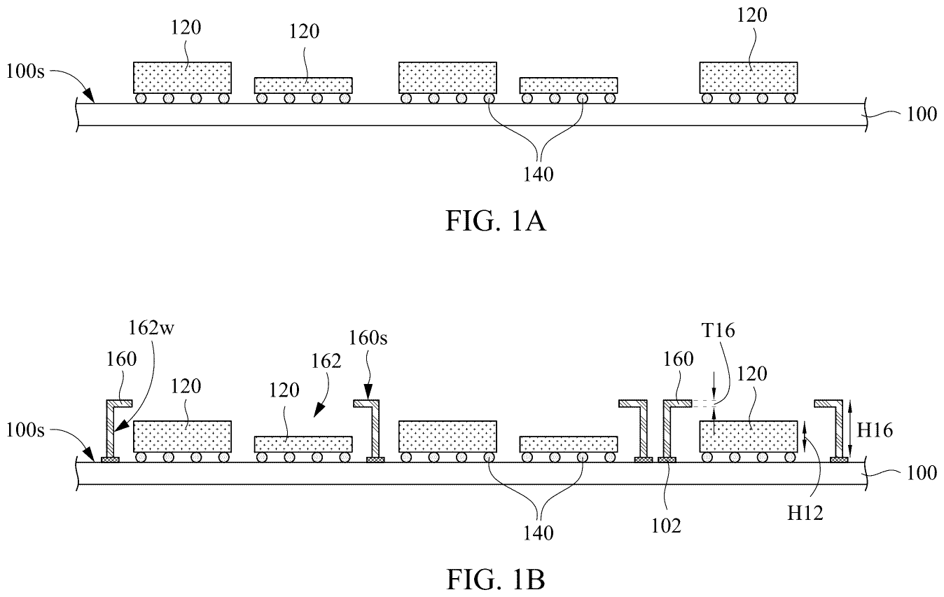

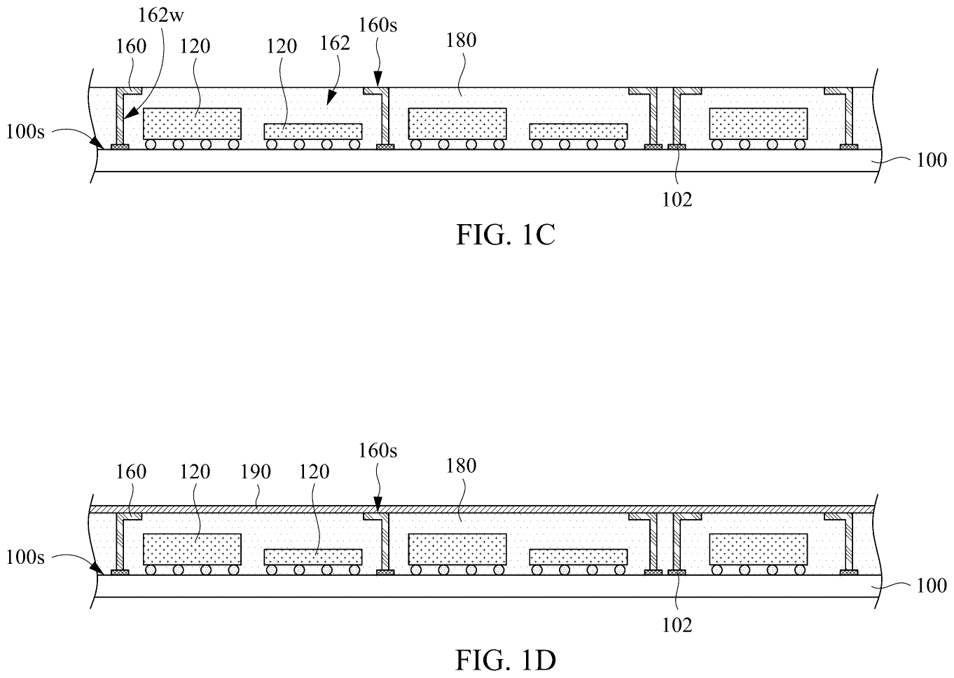

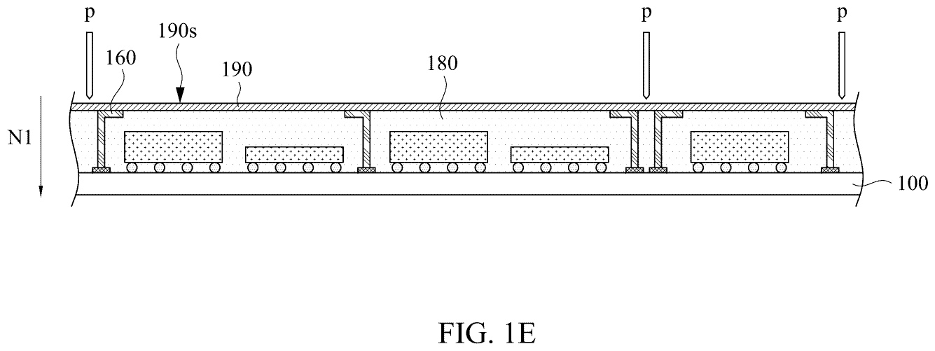

A method for fabrication of the system in package module is disclosed while FIG. 1A to FIG. 1E illustrate sequent steps of this method in accordance with at least one embodiment of present disclosure. Referring to FIG. 1A, firstly, the circuit substrate 100 which has the surface 100s on its one side is provided. Afterward, the plurality of electronic components 120 are disposed on the surface 100s of the circuit substrate 100. In addition, the circuit substrate 100 may further include at least one layer of solder mask (not shown) which may cover the surface 100s of the circuit substrate 100 and expose the plurality of pads (not shown).

Specifically, the electronic components 120 are electrically connected to the circuit substrate 100 by the plurality of solders 140 via these pads. The solders 140 may be solder balls, copper pillars or other connecting structures for electrical connection. Furthermore, the electronic components 120 may be electrically connected to the circuit substrate 100 by wire-bonding in other embodiments. The electronic components 120 may be packaged as chips or unpackaged as dies.

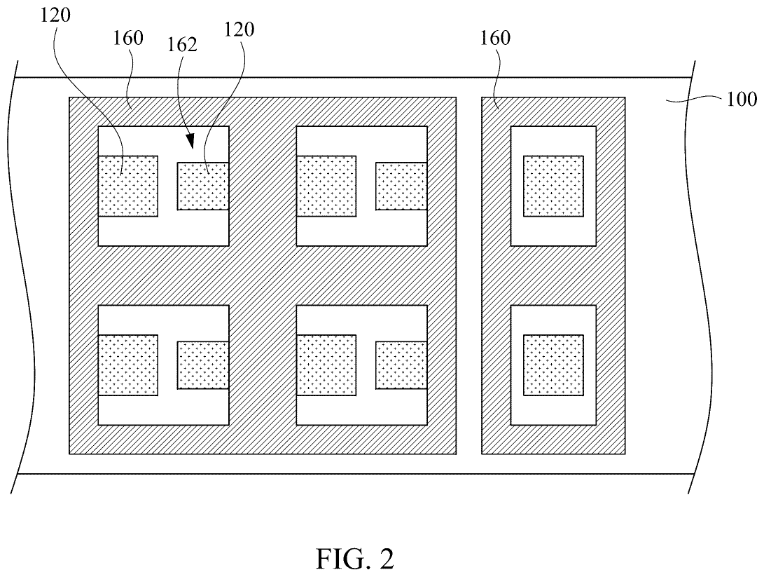

Afterward, referring to FIG. 1B and FIG. 2, the plurality of metal grids 160 are disposed on the circuit substrate 100 by the method of soldering or disposing conductive adhesives. Each of the metal grids 160 includes the plurality of openings 162, and the side wall 162w of each opening 162 encircles at least one electronic component 120 separately. To take the embodiment illustrated in FIG. 1B for example, the opening 162 of the metal grids 160 at the leftmost side of FIG. 1B encircles two electronic components 120, while the opening 162 of the metal grids 160 at the rightmost side of FIG. 1B encircles one electronic component 120. Although the quantity of the electronic components 120 which is encircled by one opening 162 is one or two in FIG. 1B, the disclosure is not limited to this embodiment. In other embodiments, each opening 162 may encircle more than two electronic components 120, such as three electronic components 120.

In addition, the circuit substrate 100 further includes the plurality of pads 102, and the metal grids 160 are electrically connected to a ground layer (not shown), e.g. a ground plane, of the circuit substrate 100 through theses pads 102. Furthermore, the step of disposing the metal grids 160 on the circuit substrate 100 includes disposing the metal grids 160 on the pads 102 of the circuit substrate 100. Since the pads 102 and the metal grids 160 are disposed on the surface 100s of the circuit substrate 100, the pads 102 and the electronic components 120 are located at the same side of the circuit substrate 100.

It is worth mentioning, the height H16 of each metal grid 160 is larger than the height H12 of each electronic component 120, so that the metal grids 160 protrude from the top surfaces of the electronic components 120. In other words, the electronic components 120 are completely located within the openings 162 of the metal grids 160. In some embodiments of the disclosure, the metal plate may be bent into the metal grids 160 which have bending parts by the method of stamping. Specifically, the metal grids 160 may be fabricated into the structures which have several “I” sections shown in FIG. 1B (in cross-sectional view) by the method of metal fabrication. However, the methods for forming the metal grids 160 of the disclosure are not limited to this embodiment. The metal grids 160 may be formed by the method of electroforming or similarity thereof, so that the structures of the metal grids 160 are not limited to the aforementioned embodiment. For instance, in some embodiments, the metal grids 160 may be fabricated into the structures which have several “T” sections in the same cross-sectional view of FIG. 1B.

Each metal grid 160 which is fabricated by stamping has the thickness T16, and the height H16 of each metal grid 160 is larger than the thickness T16 of each metal grid 160. In some embodiments, the height H16 of each metal grid 160 may be several times, such as four times, larger than the thickness T16. For instance, the thickness T16 of each metal grid 160 may range from 0.10 mm to 0.15 mm, while the height H16 of each metal grid 160 may be larger than 0.40 mm.

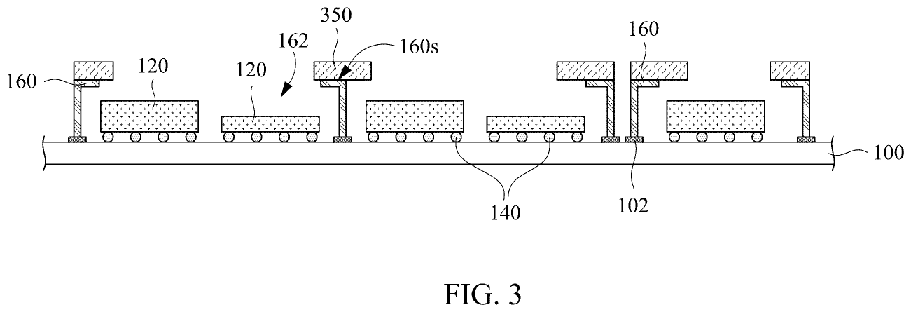

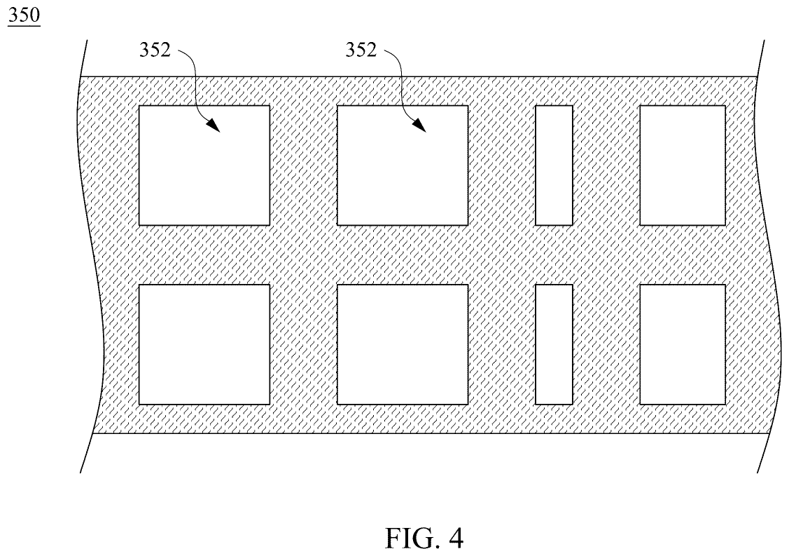

Referring to FIG. 1C, the encapsulation layer 180 is formed on the circuit substrate 100 after the electronic components 120 and the metal grids 160 are disposed. The encapsulation layer 180 covers the electronic components 120 and a part of the metal grids 160 and exposes the surfaces 160s of the metal grids 160. Specifically, referring to FIG. 3 and FIG. 4, the step of forming the encapsulation layer 180 on the circuit substrate 100 includes disposing the shielding mask 350 on the metal grids 160. The shielding mask 350 may directly touch the surfaces 160s of the metal grids 160 and expose the openings 162 of the metal grids 160. Afterward, the openings 162 are filled with the encapsulation material (not denoted) by vacuum printing to form the encapsulation layer 180. The shielding mask 350 may be a steel stencil or an alloy stencil, but the shielding mask 350 of the disclosure is not limited to be a metal stencil. For instance, the shielding mask 350 may be a ceramic stencil or an adhesive film including polymers (e.g. Polyimide tape).

The vacuum printing of this embodiment refers to squeezing the fluid encapsulation material by tools such as scrapers, so that the encapsulation material flows into the openings 162 through the openings 352 of the shielding mask 350. After the openings 162 are filled with encapsulation material, the encapsulation material is cured by thermal curing, drying or UV irradiation, and thus the encapsulation layer 180 is formed. During the process of vacuum printing, the whole object is disposed into an enclosed chamber, while this chamber is in vacuum. In vacuum, the encapsulation material may be filled in evenly, so that the potential for forming bubbles is decreased. Moreover, the method for filling with the encapsulation material of the disclosure is not limited to vacuum printing but other similar encapsulating methods thereof.

In the embodiment, the encapsulation layer 180 surrounds the side walls 162w of the openings 162 of the metal grids 160, so that the stability of the metal grids 160 is enhanced. Thus, the metal grids 160 are hardly to be shifted by external force to cause poor contact, so that the unstable electrical connection between the metal grids 160 and the pads 102 is barely occurred.

The disclosure is not limited to the embodiment. That is, the encapsulation layer 180 may not surround the side walls 162w of the openings 162 of the metal grids 160. It is worth mentioning, in some embodiments, the surfaces 160s of the metal grids 160 may be covered by the encapsulation layer 180 completely after the encapsulation layer 180 is formed. As a result, in those embodiments, the method for fabricating the system in package module further includes the step of removing a part of the encapsulation layer 180 after the encapsulation layer 180 is formed on the circuit substrate 100, so that the surfaces 160s of the metal grids 160 are exposed. The method for removing a part of the encapsulation layer 180 may be grinding or laser cutting.

Afterward, referring to FIG. 1D, the electromagnetic shielding layer 190 is formed on the encapsulation layer 180 by the method such as spray coating, sputtering, chemical plating or similarity thereof. The electromagnetic shielding layer 190 covers the electronic components 120 and is electrically connected to the metal grids 160 through the surfaces 160s of the metal grids 160. The electromagnetic shielding layer 190 may include metals (e.g. copper, nickel or alloy), conductive adhesives or other conductive materials. In addition, the electromagnetic shielding layer 190 may be an electromagnetic interference shielding film (EMI film) in some embodiments. For instance, the electromagnetic interference shielding film may be disposed on the encapsulation layer 180 by film lamination, while the electromagnetic interference shielding film may be a resin adhesive film (e.g. Polyethylene terephthalate, Polyimide or similar resin material thereof) which includes conductive (and magnetic) particles (e.g. copper, silver, iron, nickel or similar metal particles thereof). That is, the electromagnetic shielding layer 190 may include insulation materials and the conductive (and magnetic) particles distributed in the insulation materials.

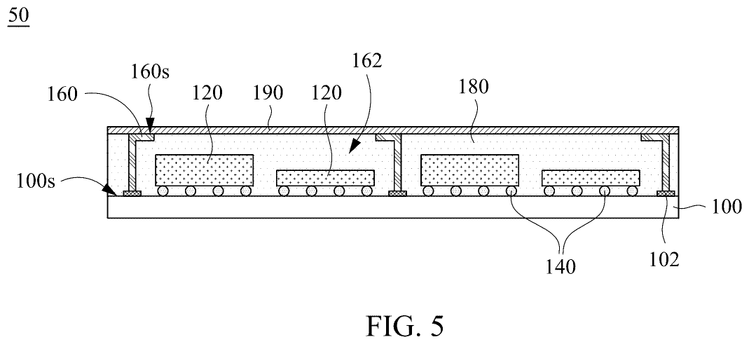

Referring to FIG. 1E, the electromagnetic shielding layer 190, the encapsulation layer 180 and the circuit substrate 100 may be cut along the spacing located between the metal grids 160 by the method such as machine cutting, laser cutting or focus ion beam cutting after the electromagnetic shielding layer 190 is formed. Specifically, the cutting devices p cut the electromagnetic shielding layer 190, the encapsulation layer 180 and the circuit substrate 100 from the surface 190s of the electromagnetic shielding layer 190 in order and cuts along with the normal N1 of the circuit substrate 100, so that the plurality of separated system in package modules are formed. The cutting devices p shown in FIG. 1E may represent cutters, laser beams or ion beams. Thus, the plurality of system in package modules 50 in FIG. 5 are completed approximately.

Referring to FIG. 5, the structure of the system in package module 50 of at least one embodiment is disclosed. The system in package module 50 includes the circuit substrate 100, the electronic components 120, the metal grid 160, the encapsulation layer 180 and the electromagnetic shielding layer 190. The circuit substrate 100 has the surface 100s, and at least two electronic components 120 are disposed on the circuit substrate 100 and located at the surface 100s of the circuit substrate 100. Although the quantity of the electronic components 120 of FIG. 1B is four, the quantity of the electronic components 120 of the disclosure is not limited to this embodiment. In other embodiments, the quantity of the electronic components 120 may be more than four, such as five.

The electronic components 120 may be passive components such as capacitors and inductors or may be active components such as transistors. However, the types of the electronic components 120 of the disclosure are not limited to the embodiment.

The metal grid 160 is disposed on the circuit substrate 100. Specifically, the electronic components 120 and the metal grid 160 are both located at the surface 100s of the circuit substrate 100, while the electronic components 120 may be electrically connected to the circuit substrate 100 by the solders 140 via the pads (not shown) of the circuit substrate 100. In addition, the metal grid 160 may be electrically connected to the circuit substrate 100 by a plurality of solders or conductive adhesives via the pads 102 of the circuit substrate 100.

The metal grid 160 includes the plurality of openings 162, and the side wall 162w (denoted in FIG. 1B) of each opening 162 encircles at least one electronic component 120 separately. In other words, more than one electronic component 120, such as two, may be disposed within each opening 162 of the metal grid 160. It is worth mentioning, referring to FIG. 1B, the height H16 of the metal grid 160 is larger than the height H12 of each electronic component 120. In some embodiments, the height H16 of the metal grid 160 may be several times, such as four times, larger than the thickness T16 of the metal grid 160.

The encapsulation layer 180 surrounds the electronic components 120 and a part of the metal grid 160 and exposes the surface 160s of the metal grid 160. Specifically, the encapsulation layer 180 covers the side surfaces and the top surfaces of the electronic components 120 and further covers the side walls 162w of the openings 162 of the metal grid 160. The materials of the encapsulation layer 180 may include insulation materials such as resins (e.g. epoxy resins) or similarities thereof. It is worth mentioning, the encapsulation layer 180 covers the pads 102 of the circuit substrate 100, so that the pads 102 are not exposed to the outer environment.

The electromagnetic shielding layer 190 covers the electronic components 120, the metal grid 160 and the encapsulation layer 180. Since the encapsulation layer 180 exposes the surface 160s of the metal grid 160, the electromagnetic shielding layer 190 may directly touch the metal grid 160 through the surface 160s. Thus the electrical connection between the electromagnetic shielding layer 190 and the metal grid 160 is achieved. Furthermore, due to the reason that the height H12 of each electronic component 120 is smaller than the height H16 of the metal grid 160, the electromagnetic shielding layer 190 does not touch the electronic components 120 (i.e. the top surfaces of the electronic components 120) directly even though the electromagnetic shielding layer 190 covers the electronic components 120.

In conclusion, the metal grids are disposed on the circuit substrate where the electronic components are disposed, so that the electromagnetic shielding in lateral direction is built up. After the encapsulation layer and the electromagnetic shielding layer on the encapsulation are formed, the spacing between the metal grids is cut, and thus the plurality of system in package modules are formed. Therefore, the connection structures of the circuit substrate (e.g. pads) which are connected to the metal grids will still be surrounded by the encapsulation layer after the cutting process, so that the connection structures are prevented from oxidation or contamination due to the exposure to environment, thereby increasing reliability of the electromagnetic shielding effect.

Furthermore, since the metal grids have provided the electromagnetic shielding effect to the package module in lateral direction, the penalized package modules are unnecessary to be cut before the deposition process of forming the electromagnetic shielding layer on the top of the package module. That is, the penalized package modules rather than the cut package modules can be disposed into the chamber during the deposition process, so that the space for disposing package modules separately can be omitted. Therefore, not only the utilization for space in chamber is improved, but also the time for cutting processing are saved, and thereby increasing the productivity of the system in package module.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A method for fabricating a system in package module, comprising:
providing a circuit substrate;
disposing a plurality of electronic components on the circuit substrate;
disposing a plurality of metal grids on the circuit substrate, and each of the plurality of metal grids comprises a plurality of openings, wherein a side wall of each of the plurality of openings encircles at least one of the plurality of electronic components separately, and a height of each of the plurality of metal grids is larger than a height of each of the plurality of electronic components;
forming an encapsulation layer on the circuit substrate after the plurality of electronic components and the plurality of metal grids are disposed, wherein the encapsulation layer covers the plurality of electronic components and a part of the plurality of metal grids and exposes a surface of the plurality of metal grids;
forming an electromagnetic shielding layer on the encapsulation layer, wherein the electromagnetic shielding layer covers the plurality of electronic components and is electrically connected to the plurality of metal grids through the surface of the plurality of metal grids; and
cutting the electromagnetic shielding layer, the encapsulation layer and the circuit substrate along a plurality of spacing located between each of the plurality of metal grids after the electromagnetic shielding layer is formed.

2. The method of claim 1, wherein each of the plurality of metal grids has a thickness, and the height of each of the plurality of metal grids is four times larger than the thickness.

3. The method of claim 1, wherein the encapsulation layer surrounds the side wall of each of the plurality of openings.

4. The method of claim 1, wherein the electromagnetic shielding layer is an electromagnetic interference shielding film.

5. The method of claim 1, wherein disposing the plurality of metal grids on the circuit substrate comprises:
disposing the plurality of metal grids on a plurality of pads of the circuit substrate, wherein the plurality of pads and the plurality of electronic components are located on the same side of the circuit substrate.

6. The method of claim 1, wherein forming the encapsulation layer on the circuit substrate comprises:
disposing a shielding mask on the plurality of metal grids, wherein the shielding mask directly touches the surface of the plurality of metal grids and exposes the plurality of openings of the plurality of metal grids; and
filling the plurality of openings with an encapsulation material by vacuum printing to form the encapsulation layer.

7. The method of claim 1, further comprising:
removing a part of the encapsulation layer to expose the surface of the plurality of metal grids after the encapsulation layer is formed on the circuit substrate.

8. A system in package module, comprising:
a circuit substrate;
at least two electronic components disposed on the circuit substrate;
a metal grid disposed on the circuit substrate, and the metal grid comprises a plurality of openings, wherein a side wall of each of the plurality of openings encircles at least one of the electronic components separately, and a height of the metal grid is larger than a height of the electronic components;
an encapsulation layer surrounding the electronic components and a part of the metal grid and exposing a surface of the metal grid; and
an electromagnetic shielding layer covering the electronic components, the metal grid and the encapsulation layer, wherein the electromagnetic shielding layer is electrically connected to the metal grid through the surface.

9. The system in package module of claim 8, wherein the metal grid has a thickness, and the height of the metal grid is four times larger than the thickness.

10. The system in package module of claim 8, wherein the electromagnetic shielding layer is an electromagnetic interference shielding film.
